(19) United States
(12) Patent Application Publication
(10) Pub. No.: US 2025/0318211 A1
(43) Pub. Date: Oct. 9, 2025

(54) Tapered Superjunction with Ultrathin P-Type Material Layer

(71) Applicant: Applied Materials, Inc., Santa Clara, CA (US)

(72) Inventor: Amirhasan NOURBAKHSH, Albany, NY (US)

(21) Appl. No.: 18/630,206

(22) Filed: Apr. 9, 2024

(51) Int. Cl. H01L 29/06; H01L 21/223; H01L 29/16

(52) U.S. Cl. CPC H10D 62/111; H01L 21/2236; H10D 62/8325

(57) ABSTRACT

Methods and structures relating to tapered superjunction structures with ultrathin p-type regions. In some embodiments, a method may comprise forming an opening in a first n-type material layer on a substrate where the opening has sidewalls with an inward taper of less than 90 degrees, forming a p-type material layer on or into the sidewalls of the first n-type material layer and into a bottom of the opening in the first n-type material layer, removing a portion of the p-type material layer at the bottom of the opening, and depositing a second n-type material layer to fill the opening. In some embodiments, the p-type material layers are formed by doping the sidewalls of the first n-type material layer with a plasma doping process or a solid-state diffusion doping process.

### FIELD

Embodiments of the present principles generally relate to semiconductor processing of semiconductor substrates.

### BACKGROUND

Superjunction (SJ) metal-oxide-semiconductor transistors (MOSFETs) have n-type layers and p-type layers arranged in vertical pillars (regions) in the drift layer of the transistor. When a voltage is applied to the transistor, the depletion layers increase horizontally, merging into each other to form a single depletion layer that is equal to the depth of the regions, allowing for increased conductivity. However, the inventor has observed that because the n-type and the p-type regions are required to have an equal amount of dopants to allow for high voltage applications (>600 volts), a majority of the superjunction volume is occupied by the p-type region which does not contribute to the conductivity. The p-type region is needed only for the charge balancing. The space occupied by the p-type region reduces the n-type volume and the current handling capacity of the superjunction.

Accordingly, the inventor has provided methods and structures that improve the performance characteristics of superjunction structures.

### SUMMARY

Methods and structures that improve the performance characteristics of SJ structures are provided herein.

In some embodiments, a method for forming a superjunction structure may comprise forming an opening in a first n-type material layer on a substrate where the opening has sidewalls with an inward taper from top to bottom, forming a p-type material layer on or into the sidewalls of the first n-type material layer and into a bottom of the opening in the first n-type material layer, removing a portion of the p-type material layer at the bottom of the opening, and depositing a second n-type material layer to fill the opening.

In some embodiments, the method may further include a superjunction structure that is part of a superjunction metal-oxide-semiconductor field-effect transistor (MOSFET), an inward taper of the sidewalls that is approximately 89 degrees to approximately 89.5 degrees, a p-type material layer is formed into the sidewalls of the first n-type material layer, a p-type material layer is formed into the sidewalls using a solid-state doping process comprising depositing a first dielectric layer on the sidewalls and the bottom where the first dielectric layer is doped with a p-type dopant, thermally annealing the superjunction structure to diffuse the p-type dopant further into the sidewalls of the first n-type material layer to form the p-type material layer, and selectively removing the first dielectric layer from the superjunction structure, a first dielectric layer that is silicon oxide doped with boron or silicon nitride doped with boron, sidewalls are coated with a second dielectric layer after selectively removing the first dielectric layer and prior to removal of the portion of the p-type material layer at the bottom of the opening, a p-type material layer that is formed into the sidewalls using a plasma doping (PLAD) process comprising generating plasma with a p-type dopant to dope the sidewalls of the first n-type material layer and thermally annealing the superjunction structure to diffuse the p-type dopant further into the sidewalls of the first n-type material layer to form the p-type material layer, sidewalls that are coated with a dielectric layer after thermally annealing the superjunction structure and prior to removal of the portion of the p-type material layer at the bottom of the opening, a first n-type material layer and a second n-type material layer that are epitaxially grown and uniformly n-doped throughout, a first n-type material layer and a second n-type material layer are n-type silicon carbide, a p-type material layer that has a p-dopant concentration of approximately 1E16/cm³ to approximately 1E18/cm³ and a first n-type material layer that has an n-dopant concentration of approximately 1E15/cm³ to approximately 1E16/cm³ and/or a p-type material layer that has a thickness of approximately 10 nm to approximately 200 nm.

In some embodiments, a superjunction structure may comprise an n-type material layer with uniform doping throughout and a p-type material layer embedded in the n-type material layer with an angled profile from top to bottom. In some embodiments, the superjunction structure may further include an angled profile that has an angle of approximately 80 degrees to approximately 89.5 degrees, an angle that is approximately 89 degrees to approximately 89.5 degrees, and/or a p-type material layer that has a thickness of approximately 10 nm to approximately 200 nm.

In some embodiments, a non-transitory, computer readable medium having instructions stored thereon that, when executed, cause a method for forming a superjunction structure, the method may comprise forming an opening in a first n-type material layer on a substrate, wherein the opening has sidewalls with an inward taper from top to bottom, forming a p-type material layer on or into the sidewalls of the first n-type material layer and into a bottom of the opening in the first n-type material layer, removing a portion of the p-type material layer at the bottom of the opening, and depositing a second n-type material layer to fill the opening.

In some embodiments, the method of the non-transitory, computer readable may further include a p-type material layer that is formed into the sidewalls using a solid-state doping process comprising depositing a first dielectric layer on the sidewalls and the bottom where the first dielectric layer is doped with a p-type dopant, thermally annealing the superjunction structure to diffuse the p-type dopant further into the sidewalls of the first n-type material layer to form the p-type material layer, and selectively removing the first dielectric layer from the superjunction structure, and/or a p-type material layer that is formed into the sidewalls using a plasma doping (PLAD) process comprising generating plasma with a p-type dopant to dope the sidewalls of the first n-type material layer and thermally annealing the superjunction structure to diffuse the p-type dopant further into the sidewalls of the first n-type material layer to form the p-type material layer.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts cross-sectional views of a graded doping n-type-based superjunction structure compared to a superjunction structure in accordance with some embodiments of the present principles.

FIG. 2 is a method of forming a superjunction structure in accordance with some embodiments of the present principles.

FIG. 3 depicts cross-sectional views of a superjunction structure with a p-type material layer formed by deposition in accordance with some embodiments of the present principles.

FIG. 4 depicts cross-sectional views of a superjunction structure formed by a plasma doping process in accordance with some embodiments of the present principles.

FIG. 5 depicts cross-sectional views of a superjunction structure formed by a solid-state diffusion doping process in accordance with some embodiments of the present principles.

FIG. 6 depicts a cross-sectional view of a sloped or tapered sidewall of a superjunction structure in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures improve the performance characteristics of superjunction (SJ) structures such as, but not limited to, metal-oxide-semiconductor field effect transistors (MOSFETs) and diodes and the like. The present techniques provide a vertical SJ structure with highly tapered trenches, ultra-thin p-type layers, and ungraded n-type trench refills. The SJ structure uses uniform n-doped thick epitaxy instead of a graded n-doped epitaxy, simplifying the n-type material refill and eliminating manufacturing problems such as dopant grading variances and the like. In addition, the present techniques SJ structure's charge-balance is insensitive to trench critical dimensions (CDs) and slope variation, unlike standard superjunctions. The tapered trench of the SJ improves trench epitaxial fill throughput significantly, yielding a double or more throughput increase. The ultrathin p-type layer also maximizes the n-type region width (Wₙ/pitch>90%), reducing specific on-state resistance (Rₛₚ) by a factor of two.

In standard tapered superjunctions, the n-type region width (Wₙ) and the p-type region width (Wₚ) vary vertically in the drift region. To achieve a charge balance to enhance the high voltage handling capability, a constant NA (p-doping concentration in trench) requires a graded ND (n-type doping concentration in trench). The graded ND requires high precision manufacturing to reduce variances, substantially slowing throughput during n-type region refill processes. The SJ structure of the present principles uses a trench filled with a constant n-type silicon that maintains uniform total Wₙ along the drift region depth, eliminating the need for graded doping of n-type material when the p-type layer width and doping concentration remain constant. Thus, the SJ structure of the present techniques simplifies the charge balance condition and avoids the challenging process and potential deviation of a graded doping profile.

Trench-based SJ devices, like diodes and MOSFETs, are in high-volume production using trench-etch and epitaxial fill processes. For devices with operating characteristics of greater than 600 volts, the SJ region needs to be greater than 40 microns in height. Designs for such devices are focused on reducing specific on-resistance (R_{on,sp}). Lower R_{on,sp} can be achieved by increasing SJ doping, but higher doping requires a smaller SJ cell pitch. Thus, the challenge lies in the fact that the R_{on,sp} is a function of SJ p-n pillar pitch and n-type semiconductor doping concentration. Efforts to reduce cell pitch in silicon SJ devices have resulted in notable R_{on,sp} reduction and SJ chip area decrease up to a point. However, further R_{on,sp} reduction requires SJ pitch scaling below 5 microns which is facing saturation due to constraints in scaling p-pillar width. Controlling the defectivity in p-type epi-trench fills in high-aspect ratio trenches is challenging and directly impacts device characteristics and manufacturing throughput. The inventors have found that common trench fill approaches involve multiple alternating deposition/etch steps for seam/void-free fill, limiting throughput exponentially with increases in trench aspect ratios (height to width). The challenges hinder trench-based SJ advancements, impacting cost-efficiency and manufacturability. In addition, wide p-type pillars limit SJ MOSFET conduction area scaling to approximately 50 percent.

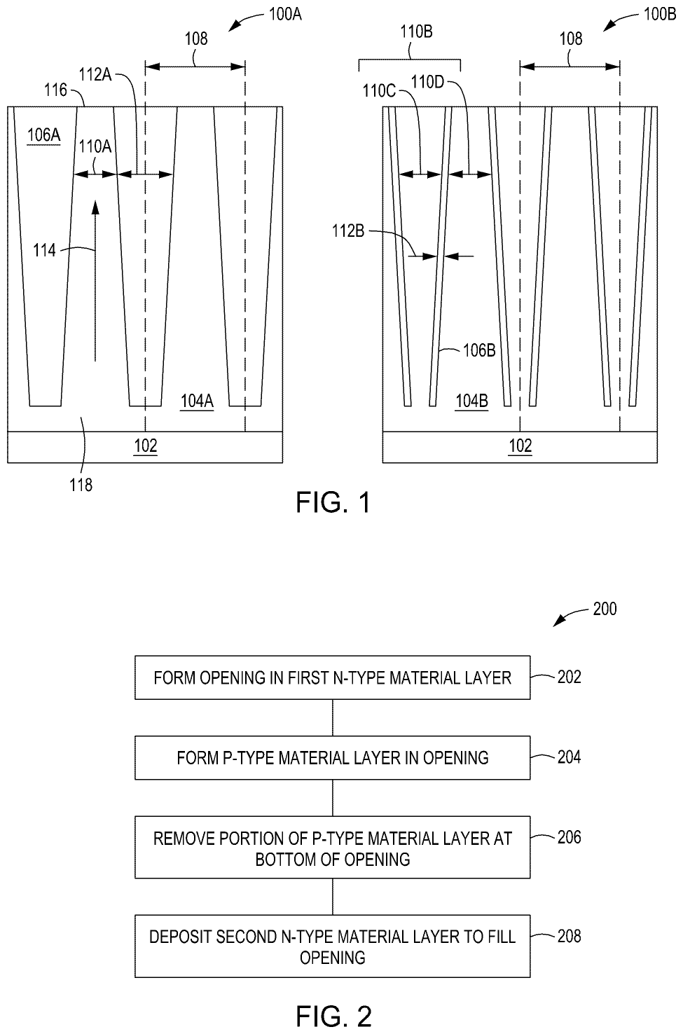

In FIG. 1, a graded doping, n-type-based SJ structure 100A is formed on a substrate 102 with p-pillar trenches 106A that are filled with p-type material. The p-pillar trenches 106A are formed on an n-type material layer 104A that has been doped with an increasing 114 (graded) doping concentration as the n-type material layer 104A extends upwards. In other words, the doping concentration of the n-type material layer 104A is highest at a top of the n-type material layer 104A and lowest at a bottom region 118 of the n-type material layer 104A. The increasing doping concentration is due to the fact that the p-type doping concentration remains constant but the widths of the n-type material layer 104A and the p-pillar trenches 106A vary at different heights of the graded doping, n-type-based SJ structure 100A. The p-pillar trench is widest at the top 116 and narrowest at the bottom region 118 while the n-type material layer 104A between the p-pillar trenches 106A is narrowest at the top 116 and widest at the bottom region 118. The SJ charge balance condition can be formulated as the (width of the n-type region (Wₙ) 110A)×(n-type doping concentration (N_{D}))=(width of the p-type region (Wₚ) 112A)×(p-type doping concentration (N_{A})). For the graded doping, n-type-based SJ structure 100A with pitch 108, Wₙ=pitch 108 minus Wₚ 112A. The graded doping profile of the n-type material layer 104A is difficult to achieve and causes variances in the characteristics of the graded doping, n-type-based SJ structure 100A.

The inventors have discovered that by using an ultrathin p-type layer 106B instead of a filled p-pillar trench 106A in an SJ structure 100B, a graded doping profile is not needed for an n-type material layer 104B, increasing throughput as the n-type material layer 104B is easier to form with a uniform doping concentration. The SJ charge balance condition for the SJ structure 100B can be formulated as the (width of the n-type region (Wₙ) 110B)×(n-type doping concentration (N_{D}))=(width of the p-type region (Wₚ) 112B)×(p-type doping concentration (N_{A})). Wₙ 110B of the SJ structure 100B is the (first n-type width (Wₙ₁) 110C)+second n-type width (Wₙ₂) 110D). For the SJ structure 100B with pitch 108, Wₙ=(Wₙ₁ 110C)+ (Wₙ₂ 110D)=pitch 108 minus 2×(Wₚ 112B). The uniform doping profile of the n-type material layer 104B is easier to achieve and dramatically reduces variances in the characteristics of the SJ structure 100B.

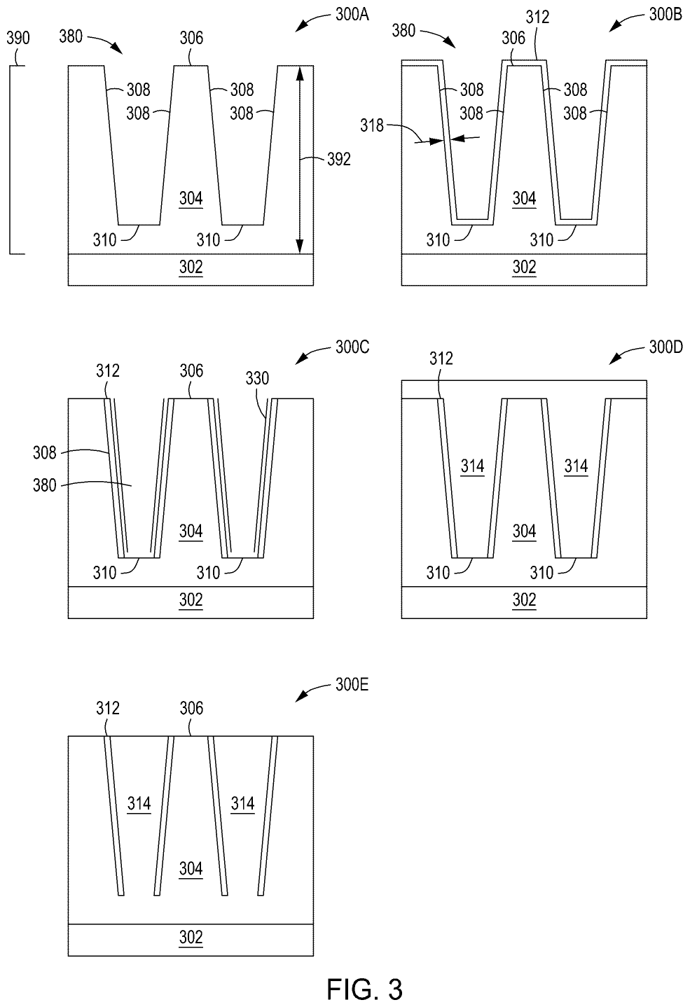

FIG. 2 is a method 200 of forming an SJ structure 390 with an ultrathin p-type layer in accordance with the present principles. In block 202, an opening 380 is formed through a top surface 306 of a first n-type material layer 304 with a uniform n-type doping concentration throughout on a substrate 302 as depicted in a view 300A of FIG. 3. In some embodiments, the critical dimension (CD) of the opening 380 may be from approximately 2 microns to approximately 10 microns. In some embodiments, the opening 380 into the first n-type material layer 304 may have a height to width aspect ratio of 15:1 to 20:1 or more, making filling of the high aspect ratio opening challenging. In some embodiments, the first n-type material layer 304 may have a uniform n-dopant concentration of approximately 1E15/cm³ to approximately 1E16/cm³. The first n-type material layer 304 may be formed by epitaxial growth on the substrate 302. In some embodiments, the first n-type material may have a thickness 392 of approximately 40 microns to approximately 50 microns. In some embodiments, the first n-type material layer 304 may be n-type silicon or n-type silicon carbide and the like. The opening 380 has sidewalls 308 and a bottom 310.

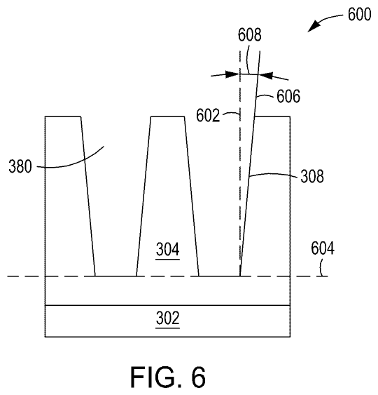

The sidewalls 308 have a slope 606 or inward taper relative to a horizontal surface 604 of the substrate 302 (such as top surface 306, etc.) as depicted in a view 600 of FIG. 6. The angle 608 of the slope 606 or taper relative to a perpendicular line 602 from the horizontal surface 604 of the substrate 302 is less than 90 degrees. In some embodiments, the angle is approximately 80 degrees to approximately 89.5 degrees. In some embodiments, the angle is approximately 89 degrees to approximately 89.5 degrees. The slope 606 or taper of the sidewalls 308 permits easier processing of the sidewalls 308 for formation of the p-type layer and also easier processing for growing epitaxial fill in the opening 380 to form a second n-type material layer discussed below. In some embodiments, the substrate 302 may be formed of n+ doped silicon material. The substrate characteristics as described above may pertain to the various method embodiments of forming the p-type material layer as discussed below.

In block 204, a p-type material layer is formed in the opening 380. The formation of the p-type material layer may be accomplished using different embodiments disclosed herein. A first embodiment will be discussed in completion before a second and third embodiment are discussed. In some embodiments as depicted in a view 300B of FIG. 3, the p-type material layer 312 is deposited onto the substrate 302 as a conformal layer. The p-type material layer 312 may be formed as a doped layer or as a non-doped layer that is subsequently doped after deposition. In some embodiments, the p-type material layer 312 is epitaxially grown on the substrate 302. In some embodiments, the p-type material layer 312 may have a p-dopant concentration of approximately 1E16/cm³ to approximately 1E18/cm³. In some embodiments, a thickness 318 of the p-type material layer 312 may be approximately 10 nm to approximately 200 nm. The thinner the p-type material layer 312, the more volume of n-type material and, subsequently, the higher the conductivity of a device incorporating the SJ structure 390 of the present techniques. The p-type material layer 312 is present for charge balancing and does not contribute to the conductivity capabilities of the SJ structure 390. The thickness 318 of the p-type material layer 312 can be adjusted to allow for higher voltage applications (e.g., greater than 600 volts and the like). Higher thicknesses of the p-type material layer 312 allow for higher voltages to be used in a device with the SJ structure 390. Designs incorporating the SJ structure 390 as described herein may be adjusted based on a tradeoff between desired operating voltage and desired current carrying capabilities.

In block 206, a bottom portion of the p-type material layer 312 is removed at the bottom 310 of the opening 380 as depicted in a view 300C of FIG. 3. In some embodiments, a thin oxide layer 330 is deposited on the sidewalls 308 of the p-type material layer 312 to protect the sidewalls 308 from subsequent etching. The thin oxide layer 330 may be a dielectric layer such as, but not limited to, thermal oxide, atomic layer deposition (ALD) silicon oxides, ALD metal oxides, ALD silicon nitrides, plasma enhanced (PE) chemical vapor deposition (CVD) oxides or nitrides and the like. An anisotropic etch process is then performed on the substrate 302 to remove the portion of the p-type material layer 312 at the bottom 310 of the opening 380. In block 208, a second n-type material layer 314 with uniform n-dopant is deposited to fill the opening 380 as depicted in a view 300D of FIG. 3. In some embodiments, the second n-type material layer 314 is epitaxially grown in the opening 380 and top surface 306. The second n-type material layer 314 can be grown at a faster rate due to the slope/taper of the sidewalls 308, increasing production throughput. The second n-type material layer 314 is the same material as the first n-type material layer 304 and grown in a similar fashion such that the same n-type material surrounds the p-type material layer 312 in the SJ structure 390. In some embodiments, a chemical mechanical planarization (CMP) process may then be performed to remove excess material from the top surface 306 of the substrate 302 as depicted in a view 300E of FIG. 3.

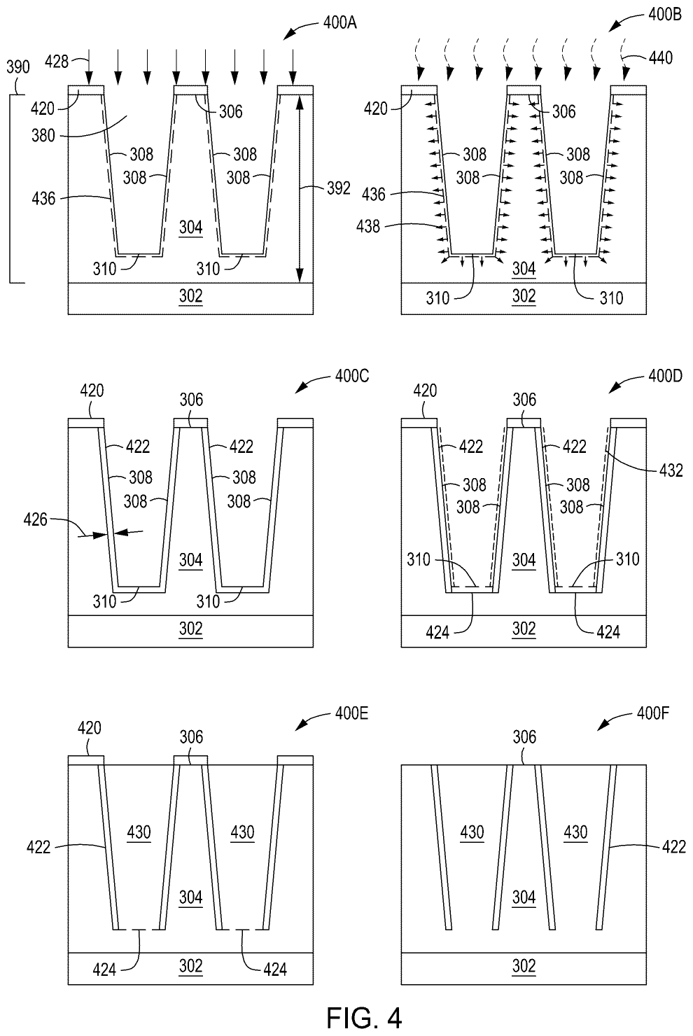

In a second embodiment for forming the p-type material layer, a substrate 302 with the first n-type material layer 304 with uniform doping uses a hardmask patterned oxide layer 420 and an etching process to form the opening 380 as depicted in a view 400A of FIG. 4 (per block 202 of the method 200). For block 204 of the method 200, the p-type material layer is formed into the sidewalls 308 and the bottom 310 of the first n-type material layer 304 by a plasma doping (PLAD) process 428. The slope/taper of the sidewalls 308 allows the plasma to reach the sidewalls 308 sufficiently to dope 436 the sidewalls 308 of the first n-type material layer 304 despite the PLAD process 428 being a surface treatment process that is highly directed perpendicular to the top surface 306 of the substrate 302. Such doping using a PLAD process is not possible with structures having perpendicular sidewalls as only the bottom of an opening would be doped during the process. The PLAD process 428 can be controlled to tune the amount and penetration of the p-type dopant into the first n-type material layer 304.

In some embodiments, the PLAD process 428 may not sufficiently penetrate into the first n-type material layer 304 enough to provide a desirable thickness for the p-type material layer for a given application. As such, an optional thermal process 440 may be used to thermally anneal the substrate 302 to further control the diffusion 438 of the p-type dopants into the sidewalls 308 of the first n-type material 304 as depicted in a view 400B of FIG. 4. The optional thermal process 440 may be accomplished by directional heating lamps, heating of the substrate directly, and/or indirect heating of the substrate and the like. In some embodiments, the p-type material layer 422 may have a p-dopant concentration of approximately 1E16/cm³ to approximately 1E18/cm³. At the completion of the PLAD process 428 or the optional thermal process 440, the p-type material layer 422 is formed in the first n-type material layer 304 with a thickness 426 of approximately 10 nm to approximately 200 nm as depicted in a view 400C of FIG. 4.

As per block 206 of the method 200, a directional dry etch process may be used to remove a bottom portion of the p-type material layer 422 from the bottom 310 of the opening 380 as depicted in a view 400D of FIG. 4. In some embodiments, an optional thin oxide layer 432 is deposited on the sidewalls 308 of the p-type material layer 422 to protect the sidewalls 308 from subsequent etching. The optional thin oxide layer 432 may be a dielectric layer such as, but not limited to, thermal oxide, ALD silicon oxides, ALD metal oxides, ALD silicon nitrides, PECVD oxides or nitrides and the like. An anisotropic dry etch process is then performed on the substrate 302 to remove the portion of the p-type material layer 422 at the bottom 310 of the opening 380. In the second embodiment, a portion of the first n-type material layer 304 is etched away such that a second bottom 424 is formed, making the opening 380 deeper than in the first embodiment. If the optional thin oxide layer 432 is used to protect the sidewalls 308, the optional thin oxide layer 432 is removed before proceeding with the fill process.

As per block 208 of the method 200, a second n-type material layer 430 is deposited to fill the opening 380 as depicted in a view 400E of FIG. 4. In some embodiments, the second n-type material layer 430 with uniform dopant is epitaxially grown in the opening 380. The second n-type material layer 430 can be grown at a faster rate due to the slope/taper of the sidewalls 308 and the non-graded doping profile, increasing production throughput. The second n-type material layer 430 is the same material as the first n-type material layer 304 and grown in a similar fashion such that the same n-type material surrounds the p-type material layer 422 in the SJ structure 390 as depicted in a view 400F of FIG. 4. In some embodiments, the first n-type material layer 304 and the second n-type material layer 430 may be formed of silicon doped with phosphorous or silicon doped with arsenic and the like for silicon-based SJ structures or n-type silicon carbide and the like for silicon carbide-based SJ structures. After completion of the formation of the second n-type material layer 430, the hardmask patterned oxide layer 420 is removed.

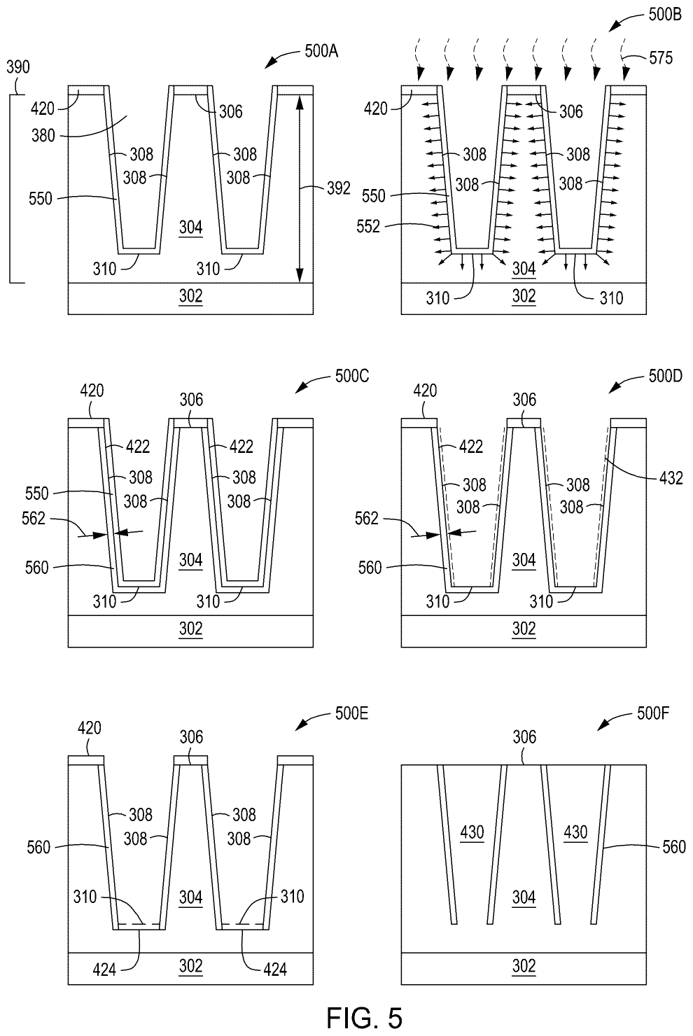

In a third embodiment for forming the p-type material layer, a substrate 302 with the first n-type material layer 304 with uniform doping uses a hardmask patterned oxide layer 420 and an etching process to form the opening 380 as depicted in a view 500A of FIG. 5 (per block 202 of the method 200). For block 204 of the method 200, the p-type material layer is formed into the sidewalls 308 and the bottom 310 of the opening 380 of the first n-type material layer 304 by a solid-state diffusion doping process. A dielectric layer 550 containing p-type dopants is first formed on the sidewalls 308 and the bottom 310 of the opening 380 (see view 500A of FIG. 5). The dielectric layer 550 may be a dielectric material such as boron doped silicon oxide or boron doped silicon nitride and the like. the dielectric layer 550 may be deposited using a CVD, PECVD, or ALD process.

A thermal annealing process 575 is then performed on the substrate 302 to diffuse 552 the p-type dopant into the first n-type material layer 304 and to activate the p-type dopant as depicted in a view 500B of FIG. 5. In some embodiments, the p-type material layer 560 may have a p-dopant concentration of approximately 1E16/cm³ to approximately 1E18/cm³. The thermal annealing process 575 can be controlled to provide a desired thickness 562 of the p-type material layer 560 as depicted in a view 500C of FIG. 5. In some embodiments, the p-type material layer 560 is formed into the first n-type material layer 304 with a thickness 562 of approximately 10 nm to approximately 200 nm. The thermal process 475 may be accomplished by directional heating lamps, heating of the substrate directly, and/or indirect heating of the substrate and the like. The dielectric layer 550 is then removed using a selective wet etch removal process as depicted in a view 500D of FIG. 5.

As per block 206 of the method 200, a directional dry etch process may be used to remove a bottom portion of the p-type material layer 560 from the bottom 310 of the opening 380 as depicted in a view 500E of FIG. 5. In some embodiments, an optional thin oxide layer 432 is deposited on the sidewalls 308 of the p-type material layer 560 to protect the sidewalls 308 from subsequent etching as depicted in the view 500D of FIG. 5. The optional thin oxide layer 432 may be a dielectric layer such as, but not limited to, thermal oxide, ALD silicon oxides, ALD metal oxides, ALD silicon nitrides, PECVD oxides or nitrides and the like. An anisotropic dry etch process is then performed on the substrate 302 to remove the portion of the p-type material layer 560 at the bottom 310 of the opening 380 (see view 500E of FIG. 5). In the third embodiment (similar to the second embodiment), a portion of the first n-type material layer 304 is etched away such that a second bottom 424 is formed, making the opening 380 deeper than with the first embodiment. If the optional thin oxide layer 432 is used to protect the sidewalls 308, the optional thin oxide layer 432 is removed before proceeding with the fill process.

As per block 208 of the method 200, a second n-type material layer 430 with uniform doping is deposited to fill the opening 380 as depicted in a view 500F of FIG. 5. In some embodiments, the second n-type material layer 430 is epitaxially grown in the opening 380. The second n-type material layer 430 can be grown at a faster rate due to the slope/taper of the sidewalls 308 and the uniform doping, increasing production throughput. The second n-type material layer 430 is the same material as the first n-type material layer 304 and grown in a similar fashion such that the same n-type material surrounds the p-type material layer 560 in the SJ structure 390 as depicted in a view 500F of FIG. 5. In some embodiments, the first n-type material layer 304 and the second n-type material layer 430 may be formed of silicon doped with phosphorous or silicon doped with arsenic and the like for silicon-based SJ structures or n-type silicon carbide and the like for silicon carbide-based SJ structures. After completion of the formation of the second n-type material layer 430, the hardmask patterned oxide layer 420 is removed.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming a superjunction structure, comprising:
forming an opening in a first n-type material layer on a substrate, wherein the opening has sidewalls with an inward taper from top to bottom;
forming a p-type material layer on or into the sidewalls of the first n-type material layer and into a bottom of the opening in the first n-type material layer;
removing a portion of the p-type material layer at the bottom of the opening; and
depositing a second n-type material layer to fill the opening.

2. The method of claim 1, wherein the superjunction structure is part of a superjunction metal-oxide-semiconductor field-effect transistor (MOSFET).

3. The method of claim 1, wherein the inward taper of the sidewalls is approximately 89 degrees to approximately 89.5 degrees.

4. The method of claim 1, wherein the p-type material layer is formed into the sidewalls of the first n-type material layer.

5. The method of claim 4, wherein the p-type material layer is formed into the sidewalls using a solid-state doping process comprising:
depositing a first dielectric layer on the sidewalls and the bottom, wherein the first dielectric layer is doped with a p-type dopant;
thermally annealing the superjunction structure to diffuse the p-type dopant further into the sidewalls of the first n-type material layer to form the p-type material layer; and
selectively removing the first dielectric layer from the superjunction structure.

6. The method of claim 5, wherein the first dielectric layer is silicon oxide doped with boron or silicon nitride doped with boron.

7. The method of claim 5, wherein the sidewalls are coated with a second dielectric layer after selectively removing the first dielectric layer and prior to removal of the portion of the p-type material layer at the bottom of the opening.

8. The method of claim 4, wherein the p-type material layer is formed into the sidewalls using a plasma doping (PLAD) process comprising:
generating plasma with a p-type dopant to dope the sidewalls of the first n-type material layer; and
thermally annealing the superjunction structure to diffuse the p-type dopant further into the sidewalls of the first n-type material layer to form the p-type material layer.

9. The method of claim 8, wherein the sidewalls are coated with a dielectric layer after thermally annealing the superjunction structure and prior to removal of the portion of the p-type material layer at the bottom of the opening.

10. The method of claim 1, wherein the first n-type material layer and the second n-type material layer are epitaxially grown and uniformly n-doped throughout.

11. The method of claim 1, wherein the first n-type material layer and the second n-type material layer are n-type silicon carbide.

12. The method of claim 1, wherein the p-type material layer has a p-dopant concentration of approximately 1E16/cm³ to approximately 1E18/cm³ and the first n-type material layer has an n-dopant concentration of approximately 1E15/cm³ to approximately 1E16/cm³.

13. The method of claim 1, wherein the p-type material layer has a thickness of approximately 10 nm to approximately 200 nm.

14. A superjunction structure, comprising:
an n-type material layer with uniform doping throughout; and
a p-type material layer embedded in the n-type material layer with an angled profile from top to bottom.

15. The superjunction structure of claim 14, wherein the angled profile has an angle of approximately 80 degrees to approximately 89.5 degrees.

16. The superjunction structure of claim 15, wherein the angle is approximately 89 degrees to approximately 89.5 degrees.

17. The superjunction structure of claim 14, wherein the p-type material layer has a thickness of approximately 10 nm to approximately 200 nm.

18. A non-transitory, computer readable medium having instructions stored thereon that, when executed, cause a method for forming a superjunction structure, the method comprising:
forming an opening in a first n-type material layer on a substrate, wherein the opening has sidewalls with an inward taper from top to bottom;
forming a p-type material layer on or into the sidewalls of the first n-type material layer and into a bottom of the opening in the first n-type material layer;
removing a portion of the p-type material layer at the bottom of the opening; and
depositing a second n-type material layer to fill the opening.

19. The non-transitory, computer readable medium of claim 18, wherein the p-type material layer is formed into the sidewalls using a solid-state doping process comprising:
depositing a first dielectric layer on the sidewalls and the bottom, wherein the first dielectric layer is doped with a p-type dopant;
thermally annealing the superjunction structure to diffuse the p-type dopant further into the sidewalls of the first n-type material layer to form the p-type material layer; and
selectively removing the first dielectric layer from the superjunction structure.

20. The non-transitory, computer readable medium of claim 18, wherein the p-type material layer is formed into the sidewalls using a plasma doping (PLAD) process comprising:
generating plasma with a p-type dopant to dope the sidewalls of the first n-type material layer; and
thermally annealing the superjunction structure to diffuse the p-type dopant further into the sidewalls of the first n-type material layer to form the p-type material layer.
